(19) United States
(12) Patent Application Publication
(10) Pub. No.: US 2025/0079870 A1
(43) Pub. Date: Mar. 6, 2025

(54) SIMULATED DATASET GENERATION AND MODEL PRETRAINING FOR SIMULTANEOUS PARAMETER IDENTIFICATION, STATE ESTIMATION, AND PREDICTION OF BATTERY SYSTEM RESPONSE IN BATTERY MANAGEMENT SYSTEMS

(71) Applicant: Cuberg, Inc., San Leandro, CA (US)

(72) Inventor: Maxwell Dylla, Oakland, CA (US)

(73) Assignee: Cuberg, Inc., San Leandro, CA (US)

(21) Appl. No.: 18/457,503

(22) Filed: Aug. 29, 2023

(51) Int. Cl. H02J 7/00; G01R 31/367

(52) U.S. Cl. CPC H02J 7/0071; G01R 31/367; H02J 7/00712

(57) ABSTRACT

Control profiles may be determined for a designated type of battery system. The control profiles may define patterns of charging and/or discharging the designated type of battery system over time. Simulated battery values may be determined by applying one or more physics models to the control profiles. The physics models may model interactions between states. A pre-trained battery value temporal convolutional neural network may be determined based on a timeseries pre-training dataset that includes the control profiles and the simulated battery values. One or more predicted battery values may be determined based on application of the temporal convolutional neural network to a prospective control profile and observed battery system input values for a designated battery system of the designated type of battery system. An operational instruction may be sent to the designated battery system based on the one or more predicted battery values.

### FIELD OF TECHNOLOGY

This patent application relates generally to battery management technologies, and more specifically to artificial intelligence and machine learning approaches to battery data value prediction in battery management systems.

### BACKGROUND

Predicting battery system data values is important for a variety of applications. In the absence of accurate prediction, a device that depends on a battery system for power may suffer unexpected power loss. Unanticipated power loss can lead to negative outcomes such as failure to complete a task, damage to the device itself, damage to other objects, or injury to people. Battery system state prediction is thus increasingly important as an ever-growing number of devices transition to a battery-powered configuration.

However, battery systems exhibit complex behavior that is difficult to predict. Different combinations of battery histories, current battery values, operating conditions, control profiles, and other such characteristics mean that predicting a future state, such as an amount of charge remaining at a particular point in time in the future, is a difficult task. Conventional techniques for battery state prediction suffer from inaccuracy. Moreover, many conventional techniques are tailored to particular types of batteries, devices, operating conditions, and the like. A challenge of particular note is referred to as a “cold start” problem. A battery system may rely on a prediction model to generate predictions as to future performance. However, until the system is deployed, a lack of available data may prevent the training of such a prediction model. Accordingly, improved systems and methods for battery system state prediction are needed.

### SUMMARY

Techniques and mechanisms described herein provide for systems, methods, and non-transitory computer readable media for battery management and analysis. In some embodiments, a plurality of control profiles may be determined for a designated type of battery system. Each control profile may define a respective pattern of charging and/or discharging the designated type of battery system over a period of time. A plurality of simulated battery values may be determined by applying one or more physics models to the plurality of control profiles via a processor. The one or more physics models may model interactions between a plurality of states associated with the designated type of battery system. A pre-trained battery value temporal convolutional neural network may be determined based on a timeseries pre-training dataset that includes the plurality of control profiles and the plurality of simulated battery values. A prospective control profile and observed battery system input values may be received as input for a designated battery system of the designated type of battery system. A predicted one or more battery values may be determined for the designated battery system based on application of the temporal convolutional neural network to the prospective control profile and the observed battery system input values. An operational instruction may be transmitted to the designated battery system based on the predicted one or more battery values.

In some embodiments, determining the pre-trained battery state for the designated battery system may involve introducing a plurality of blanked outcome values into the timeseries pre-training dataset. The pre-trained battery value temporal convolutional neural network may be trained based on gradient descent via loss function reflecting a difference between predicted outcome values and blanked outcome values.

In some implementations, determining the pre-trained battery state for the designated battery system may involve introducing a plurality of intermittent blanked values simulating missing data in the timeseries pre-training dataset.

In some embodiments, determining the plurality of control profiles may involve accessing a database storing field data characterizing operation of one or more physical battery systems over time. Alternatively, or additionally, determining the plurality of control profiles may involve generating a function over time, the function being of a sinusoidal or sigmoid form.

In some embodiments, the one or more physics models may include a pseudo two-dimensional model characterizing one or more electrochemical processes with the designated type of battery system. The predicted one or more battery values may include an electrolyte connectivity value or a cathode conductivity value.

In some embodiments, the one or more physics models may include an equivalent circuit model characterizing one or more operational characteristics of the designated type of battery system. The predicted one or more battery values may include a resistance value or a capacitance value.

In some implementations, a designated control profile of the plurality of control profiles may include a designated current profile defining an amount of current over a designated period of time. Alternatively, or additionally, a designated control profile of the plurality of control profiles may include a designated power profile defining an amount of power over a designated period of time.

In some embodiments, the predicted one or more battery values may include a voltage value. Alternatively, or additionally, the predicted one or more battery values may include one or more of: an open-circuit voltage value, an internal resistance value, an external resistance value, a battery system temperature value, a state-of-charge value, and a state of health value.

In some embodiments, the temporal convolutional neural network may include an input layer comprising a plurality of input neurons. A subset of the input neurons may correspond to input battery data values observed of a plurality of time intervals. The input battery data values may include control profile values encoding information corresponding with the plurality of control profiles.

In some implementations, the temporal convolutional neural network may include one or more hidden layers each comprising a respective plurality of hidden layer neurons. A designated hidden layer neuron may receive as input data values corresponding to a respective two or more different time periods. The designated hidden layer neuron may include an activation function configured to transmit an output signal to a recipient neuron based on the input data values. The hidden layers collectively perform time-dilation on a plurality of input values spread over a period of time to predict an output value corresponding to a single period of time.

These and other embodiments are described further below with reference to the figures.

### BRIEF DESCRIPTION OF THE DRAWINGS

The included drawings are for illustrative purposes and serve only to provide examples of possible structures and operations for the disclosed inventive systems, apparatus, methods, and computer program products for battery data value prediction and device management. These drawings in no way limit any changes in form and detail that may be made by one skilled in the art without departing from the spirit and scope of the disclosed implementations.

FIG. 1 illustrates an overview method for a battery value temporal convolutional neural network.

FIG. 2 illustrates a flow diagram of a process flow performed in accordance with one or more embodiments.

FIG. 3 is a block diagram of battery pack that may be used in conjunction with techniques and mechanisms described herein.

FIG. 4 illustrates one example of a computing system.

FIG. 5A illustrates a conceptual diagram of a prediction framework for a battery system in an inference phase.

FIG. 5B illustrates a conceptual diagram of a prediction framework for a battery system in a training phase.

FIG. 6 illustrates a diagram of a battery value temporal convolutional neural network, configured in accordance with one or more embodiments.

FIG. 7 illustrates an overview method of training a battery value temporal convolutional network.

FIG. 8 illustrates a method for determining a battery value temporal convolutional neural network pre-training dataset, performed in accordance with one or more embodiments.

FIG. 9 illustrates a method for training a battery value temporal convolutional neural network, performed in accordance with one or more embodiments.

FIG. 10A, FIG. 10B, FIG. 10C, and FIG. 10D illustrate examples of plots generated in accordance with one or more embodiments.

FIG. 11A, FIG. 11B, FIG. 11C, and FIG. 11D illustrate examples of plots generated in accordance with one or more embodiments.

FIG. 12 illustrates a method of controlling a device, performed in accordance with one or more embodiments.

FIG. 13 illustrates a method of controlling a fleet of devices, performed in accordance with one or more embodiments.

FIG. 14 illustrates a method of predicting a value associated with a battery system, performed in accordance with one or more embodiments.

FIG. 15 illustrates a method of determining a perturbed control profile, performed in accordance with one or more embodiments.

### DETAILED DESCRIPTION

### Introduction

Techniques and mechanisms described herein provide for battery management systems in which future system values may be predicted based on current and past system values using a battery value temporal convolutional neural network. In some embodiments, a battery value temporal convolutional neural network may include an input layer of neurons corresponding to battery system data over a period of time, and an output layer of neurons corresponding to battery system predictions at particular points in time. One or more hidden layers of neurons between the input layer and the output layer may provide for time dilation, allowing a prediction for a particular point in time to be made based on input from a window of time into the past coupled with a candidate control profile defining a current profile and/or power profile applied to the battery system. According to various embodiments, the battery value temporal convolutional neural network may be pre-trained using simulated data determined by applying one or more physics models to sample parameter values and control profiles. The pre-trained model may then be trained using additional observed data determined, for instance, via a laboratory environment.

As used herein, the term “control profile” refers to a pattern of control for a battery system over time. For example, a control profile may define a current profile specifying an amount of current applied over time. As another example, a control profile may define a power profile specifying an amount of power extracted from a battery system over time.

Some conventional techniques provide for predicting some future aspects of a battery system. However, conventional techniques typically involve training separate prediction models for separate aspects of a battery system, such as separate models for parameter identification, state estimation, and response. In contrast, various embodiments of techniques and mechanisms described herein provide for combining parameter identification, state estimation, and the prediction of future battery system responses into a single learned task inside a neural network provide for holistic system inference.

Conventional approaches for predicting future aspects of a battery system suffer from a lack of accuracy, speed, and reliability. In contrast, various embodiments of techniques and mechanisms described herein provide for improved accuracy, speed, and/or reliability. By combining different prediction tasks into a single neural network, prediction speed, accuracy, and/or reliability may be improved.

According to various embodiments, techniques and mechanisms described herein are applicable in a wide range of contexts. For example, a device may be tasked with performing an action but may have several ways in which the action could be performed. In such a situation, candidate control profiles may be created that correspond with the various ways in which the action could be performed. A battery value temporal convolutional neural network may then be applied to these candidate control profiles to select a course of action consistent one or more criterion, such as sufficient battery usage. As another example, a fleet management system may be managing a fleet of devices that vary in characteristics such as a condition, state of charge, and location. In order to accomplish a set of tasks, the fleet management system may need to determine a set of devices and/or control profiles such that the fleet is collectively able to perform the set of tasks.

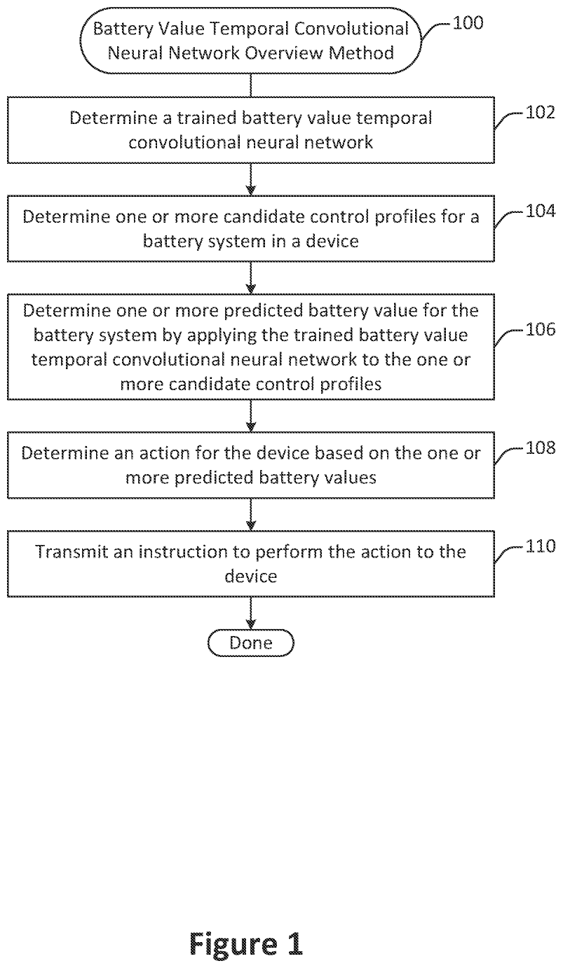

FIG. 1 illustrates an overview method 100 for a battery value temporal convolutional neural network. In some implementations, operations shown in the overview method 100 may be performed at any suitable computing system. For example, various operations may be performed in an embedded device, a battery management system, and/or at a remote server in communication with a device that includes a battery system.

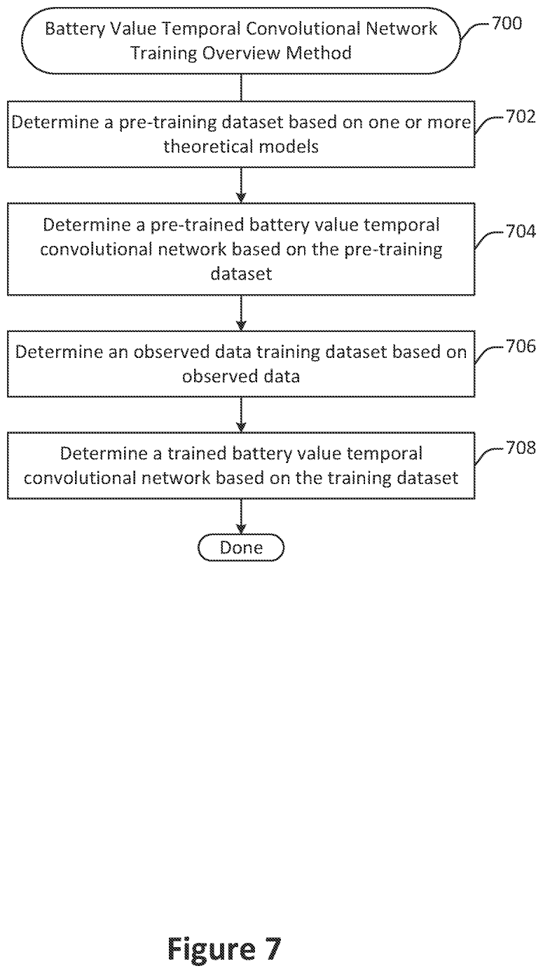

A trained battery value temporal convolutional neural network is determined at 102. In some embodiments, determining the trained battery value temporal convolutional neural network may involve determining a pre-training data set by simulating data using one or more physics models. Alternatively, or additionally, an observed data training dataset may be determined based on observed data. The battery value temporal convolutional neural network may be trained by selectively blanking battery values in observations in the training dataset, predicting the blanked battery values, and updating the battery value temporal convolutional neural network based on the accuracy of the predicted battery values as compared to the blanked battery values. Additional details regarding techniques and mechanisms for training a battery value temporal convolutional neural network are discussed throughout the application, and particularly with respect to FIG. 7 through FIG. 11.

One or more candidate control profiles for a battery system in a device is determined at 104. According to various embodiments, a candidate control profile may include a pattern of charge and/or discharge rate over time. For instance, a candidate control profile may be determined based on a potential course of action for the device. Depending on the application, multiple candidate control profiles may be determined for one or more devices, for instance to determine an acceptable device for performing a particular course of action and/or an acceptable control profile for applying to the device.

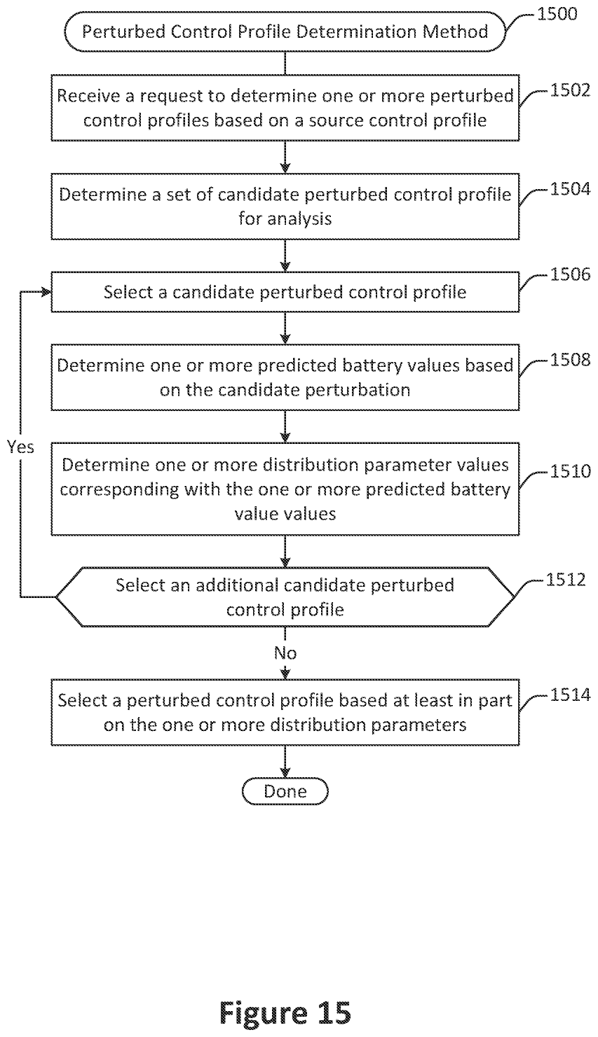

In particular embodiments, a candidate control profile may be perturbed by altering it in various ways. Such an approach may be employed for various reasons, such as to identify a control profile associated with battery values that are predictable by the battery value temporal convolutional neural network with greater accuracy than other control profiles. Additional details regarding control profile perturbation are discussed throughout the application, and particularly with respect to FIG. 15.

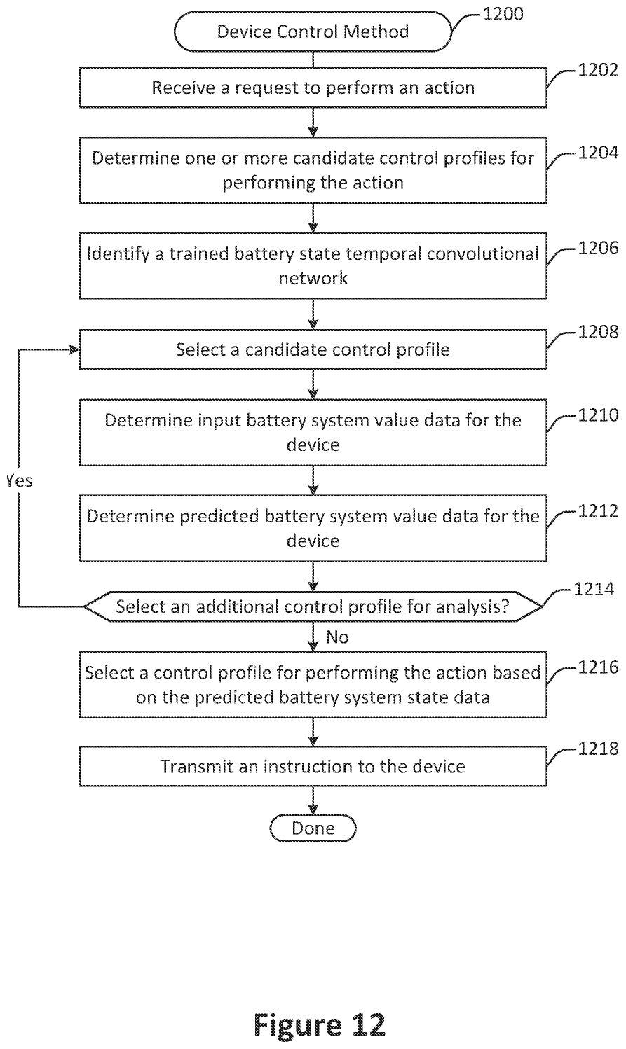

One or more predicted battery values for the battery system are determined at 106 by applying the trained battery value temporal convolutional neural network to the one or more candidate control profiles. An action for the device is determined at 108 based on the one or more predicted battery values. An instruction to perform the action is transmitted to the device at 110. Additional details regarding the application of a battery value temporal convolutional neural network to make predictions and determine courses of action based on those predictions are discussed throughout the application, and particularly with respect to FIG. 12 through FIG. 14.

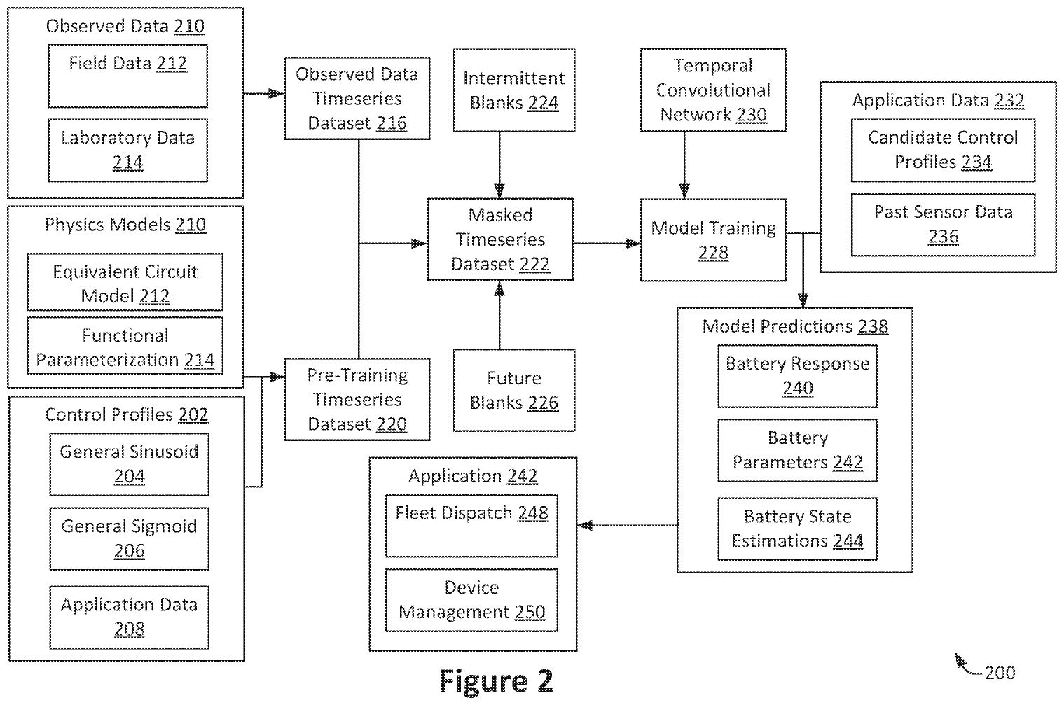

FIG. 2 illustrates a flow diagram of a process flow 200 performed in accordance with one or more embodiments. At a high level, the process flow 200 illustrates operations performed in the training and application of a battery value temporal convolutional neural network.

According to various embodiments, a battery value temporal convolutional neural network may be trained based on a pre-training timeseries dataset 220 and/or an observed data timeseries dataset 216. For instance, a model may be initially trained on a pre-training timeseries dataset 220 and then updated based on an observed data timeseries dataset 216 as additional data becomes available.

In some embodiments, an observed data timeseries dataset 216 may be determined based on observed data 210. The observed data 210 may include laboratory data 214 collected from a laboratory environment, for instance by subjecting a battery system to various conditions and control profiles and observing state data for the battery system collected by one or more sensors. Alternatively, or additionally, the observed data 210 may include field data 212 collected from battery systems deployed to devices in a field environment.

In some embodiments, a pre-training timeseries dataset 220 may be determined based on one or more control profiles 202 applied to one or more physics models 210. A control profile represents a set of conditions for charging and/or discharging the battery system. For instance, a control profile may specify a current profile and/or power profile for the battery system over a period of time.

In some implementations, a control profile may be a simulated profile determined based on a mathematical functional form. Examples of such control profiles include general sinusoid control profiles 204 and general sigmoid control profiles 206, although other functional forms may also be used. Alternatively, or additionally, a control profile may be determined based on application data 208 that reflects real-world conditions of battery systems deployed to a field environment.

In some embodiments, predicted battery system values may be determined for a battery system by applying one or more physics models 210 to a control profile. A physics model may include an equivalent circuit model 212 that captures theoretical physical characteristics of a battery system, initialized using a functional parameterization 214 that specifies one or more characteristics of the operation of the battery system.

According to various embodiments, a masked timeseries dataset 222 (also referred to herein as a blanked dataset) may be determined based on one or more observed data timeseries datasets and/or one or more pre-training timeseries datasets 220. Determining a masked timeseries dataset 222 may involve masking, or blanking, one or more values in the input dataset. For example, a future value such as a battery voltage may be masked for training purposes. The model may then be tasked with predicting the masked value, and the model's weights updated based on a loss value determined by comparing the predicted value with the actual value that was masked. As another example, one or more intermittent blanks may be introduced into a dataset to reflect the fact that real-world data for battery systems often includes missing values.

At 228, a temporal convolutional network 230 is trained using the masked timeseries dataset 222. In some embodiments, training the model may involve training an entirely new model. Alternatively, an existing model may be updated, for instance to reflect newly received training data.

The trained model is used in conjunction with application data 232 to produce one or more model predictions at 238. The application data 232 may include one or more candidate control profiles 234 for which predicted battery value information is desired. The application data 232 may also include past sensor data 236 for use in predicting the future battery value information.

According to various embodiments, the model predictions 238 may include any or all of a variety of types of information, collectively referred to as “battery data values”. The battery data values included in the model predictions 238 may include one or more battery response values 240, one or more battery parameter values 242, and/or one or more battery state values 244. For example, battery response values 240 may include data such as terminal voltage or battery temperature. As another example, battery parameter values 242 may include underlying parameters of a physics model such as resistance values, capacitance values, or open circuit voltage. Parameter values may include hidden battery parameters that are not directly observable. As yet another example, battery state values 244 may include information such as state of charge or state of health.

Model predictions 238 may be used in any of a variety of applications 242. For example, model predictions may be employed to select a device and/or control profile for performing an action in a fleet dispatch context 248. As another example, model predictions may be employed to determine a particular course of action in a device management context 250.

### Examples of Battery Systems

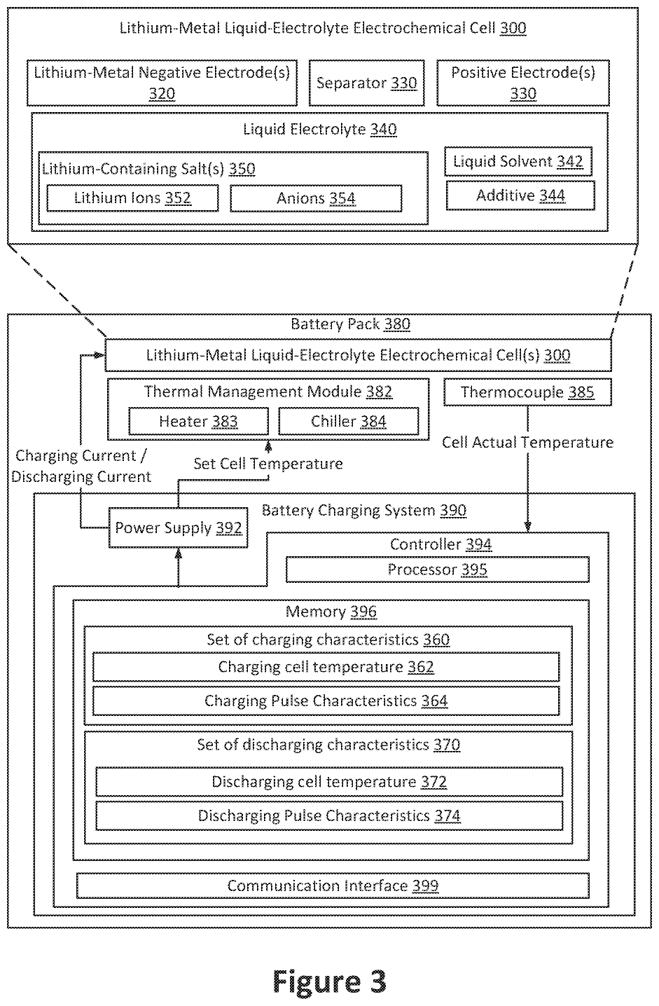

FIG. 3 is a block diagram of battery pack 380 that may be used in conjunction with techniques and mechanisms described herein. However, techniques and mechanisms described herein are applicable to a wide range of battery systems, and are not limited to the battery pack shown in FIG. 3.

The battery pack 380 comprises a lithium-metal liquid-electrolyte electrochemical cell 300, illustrating various additional components of battery pack 380, in accordance with some examples. Lithium-metal liquid-electrolyte electrochemical cell 300 comprises lithium-metal negative electrode 320, positive electrode 330, and separator 310, which is disposed and provides electronic isolation between lithium-metal negative electrode 320 and positive electrode 330. Lithium-metal liquid-electrolyte electrochemical cell 300 also comprises liquid electrolyte 340 which provides ionic transfer between lithium-metal negative electrode 320 and positive electrode 330. For example, liquid electrolyte 340 soaks separator 310 or, more specifically, the pores of separator 310.

Some examples of liquid electrolyte 340 include, but are not limited to, a mixture of one or more lithium-containing salts 350 and one or more liquid solvents 342. Some examples of lithium-containing salts 350 include, but are not limited to, lithium bis(fluorosulfonyl)imide (LiFSI), lithium bis(trifluoromethylsulfonyl)amide (LiTFSI), lithium tetrafluoroborate (LiBF₄), lithium hexafluorophosphate (LiPF₆), lithium bis(oxalato) borate (LiBOB), lithium difluoro (oxalato) borate (LiDFOB), lithium trifluoromethanesulfonate (LiTf), lithium nitrate (LiNO₃), and various combinations thereof. In some examples, lithium-containing salts 350 are LiFSI or LiTFSI, e.g., preferably LiFSI. Lithium-containing salts 350 are configured to dissociate into lithium ions 352 and anions 354. Some examples of liquid solvents 342 but are not limited to, one or more cyclic ethers (e.g., 3,3-dioxane (DOL), 3,4-dioxane (DX), tetrahydrofuran (THF)), one or more linear ethers (e.g., dimethoxyethane (DME), Bis(2-methoxyethyl) ether (G2), triethylene glycol dimethyl ether (G3), or tetraethylene glycol dimethyl ether (G4), Bis(2,2,2-trifluoroethyl) ether (BTFE); ethylal; 3,1,2,2-tetrafluoroethyl 2,2,3,3-tetrafluoropropyl ether (TFPE)), and combination thereof.

Liquid electrolyte 340 can comprises various additives 344, e.g., metal salts (e.g., having bis(trifluoromethanesulfonyl)imide (TFSI), bis(fluorosulfonyl)imide (FSI), hexafluorophosphate (PF₆), tetrafluoroborate (BF₄), and/or bis(oxalate) borate (BOB) anions), ionic liquids (eg . . . , propyl-methyl-pyrrolidinium-FSI/TFSI; butyl-methyl-pyrrolidinium-FSI/TFSI; octyl-methyl-pyrrolidinium-FSI/TFSI, and any combination thereof), and the like.

In some examples, liquid electrolyte 340 can have a viscosity of at least 35 cP or, more specifically, at least 25 cP, at least 50 cP, or even at least 300 cP at room temperature. High viscosity can be driven by specific components needed in liquid electrolyte 340 to enable the functioning of liquid electrolyte 340 in lithium-metal liquid-electrolyte electrochemical cell 300.

Positive electrode 330 can include a current collector (e.g., an aluminum foil) and an active material layer comprising an active material (e.g., in a form of particles) and a binder (e.g., a polymer binder). Some examples of positive active materials include, but are not limited to, lithium nickel manganese cobalt (NMC) oxides, lithium iron phosphate, and the like. Some examples of suitable binders include, but are not limited to, polymer binders (e.g., polyvinylidene-fluoride (PVDF), styrene butadiene rubber (SBR), and carboxyl methyl cellulose (CMC)). In some examples, positive electrode 330 comprises a conductive additive (e.g., carbon black/paracrystalline carbon).

Negative electrode 330 can also include a current collector on which a lithium metal layer is deposited when lithium-metal electrochemical cell 310 is charged. Some examples of suitable current collectors include, but are not limited to, lithium (remaining after full discharged), copper, nickel, aluminum, stainless steel, a metalized polymer substrate (e.g., metalized with copper), and a carbon-coated metal substrate. The purpose of using a negative electrode with a lithium-metal layer deposited on a current collector (in lithium-metal electrochemical cells) is to reduce the size of the negative electrode (e.g., in comparison to lithium-ion cells). For example, the thickness of the lithium-metal layer can be less than 20 micrometers. Furthermore, the addition of a current collector also helps to keep the thickness of the lithium-metal layer small. For example, the thicknesses of less than 20 micrometers are difficult to achieve with a freestanding lithium foil. As such, lithium-metal cells with negative electrodes formed by freestanding lithium foils/layers require substantially more lithium than lithium-metal cells with negative electrodes formed by a combination of a current collector and a lithium-metal layer (to achieve the same cell capacity). Lower amounts of lithium are highly desirable from the safety perspective as less lithium ejecta (e.g., molten lithium ejecta) needs to be contained when the cell goes into a thermal runaway.

Positive electrode 330, lithium-metal negative electrode 320, separator 310, and liquid electrolyte 340 can be referred to as internal components of lithium-metal electrochemical cell 310. These internal components are sensitive to moisture and other ambient conditions and insulated from the environment by a cell enclosure, such as a metal (e.g., aluminum) case (e.g., for cylindrical or prismatic cells), a pouch laminate, an aluminum-coated polymer (e.g., polyamide, polyester, polyurethane, and polypropylene).

Battery pack 380 can include any number of lithium-metal liquid-electrolyte electrochemical cells 300, e.g., one, two, three, or more. Multiple lithium-metal liquid-electrolyte electrochemical cell 300 can be used with various types of in-series and/or parallel connections to boost the voltage and/or capacity of battery pack 300.

In some examples, battery pack 380 comprises thermocouple 385 to measure the temperature of lithium-metal liquid-electrolyte electrochemical cell 300. These temperature measurements can be used to trigger various charge and/or discharge operations as further described below. Furthermore, battery pack 380 can include thermal management module 382 for changing the temperature of lithium-metal liquid-electrolyte electrochemical cell 300. Thermal management module 382, when one is present, is thermally coupled to lithium-metal liquid-electrolyte electrochemical cell 300. Thermal management module 382 can include one or both heater 382 (e.g., a resistive heater) and chiller 384 (e.g., a liquid-cooled plate). Alternatively, lithium-metal liquid-electrolyte electrochemical cell 300 can be self-heated, e.g., using an AC excitation profile as further described below. The cooling of lithium-metal liquid-electrolyte electrochemical cell 300 can be provided by the environment.

In some examples, battery pack 380 comprises battery charging system 390 for controlling charge and discharging characteristics of lithium-metal liquid-electrolyte electrochemical cell 300. Battery charging system 390 can comprise power supply 392 configured to flow an electric current through lithium-metal liquid-electrolyte electrochemical cell 300 in accordance with the set of charging characteristics while charging lithium-metal liquid-electrolyte electrochemical cell 300 and in accordance with the set of discharging characteristics while discharging lithium-metal liquid-electrolyte electrochemical cell 300. Various examples of these characteristics are described below.

In some examples, battery charging system 390 comprises controller 394, communicatively coupled to power supply 392 and configured to control the operations of power supply 392, e.g., by providing the set of charging characteristics and the set of discharging characteristics. Controller 394 can also be communicatively coupled to thermocouple 385 and receive the temperature of lithium-metal liquid-electrolyte electrochemical cell 300, which is used for various control functions. Controller 394 can also be communicatively coupled to thermal management module 382 to control the operation of thermal management module 382 (e.g., heat or cool lithium-metal liquid-electrolyte electrochemical cell 300 to a set cell temperature).

In some examples, controller 394 comprises processor 395 and memory 396, e.g., storing set of charging characteristics 360 and set of discharging characteristics 370. For example, set of charging characteristics 360 comprises charging cell temperature 362, while set of discharging characteristics 370 comprises discharging cell temperature 372 such that charging cell temperature 362 is higher than discharging cell temperature 372. In the same or other examples, set of charging characteristics 360 comprises charging pulse characteristics 364, while set of discharging characteristics 370 comprises discharging pulse characteristics 364. For example, each pair of charging pulses is separated by a discharging pulse.

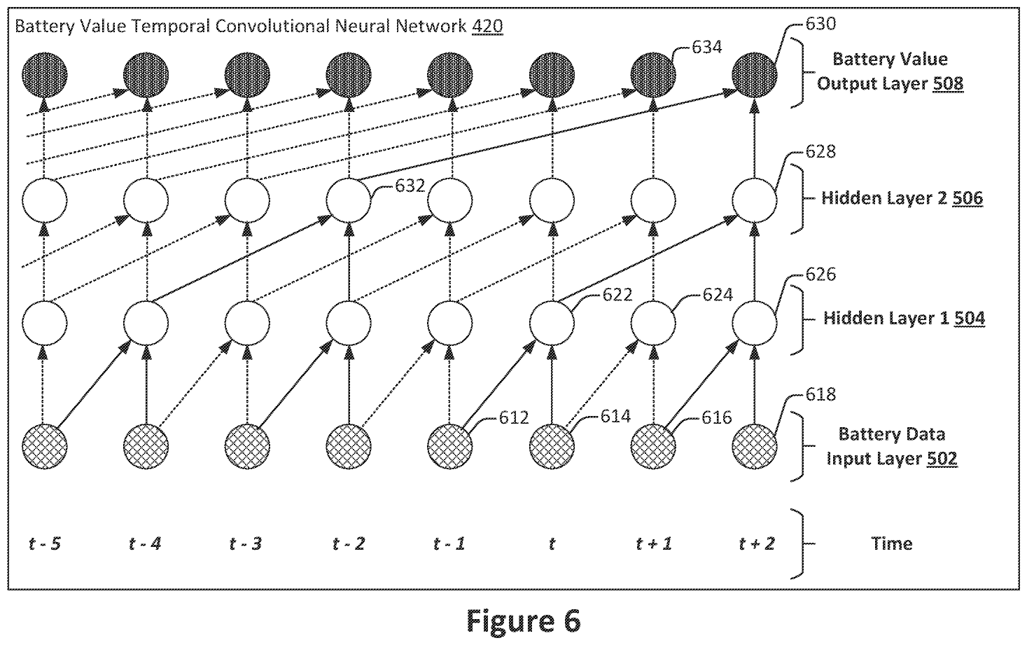

In some embodiments, the processor 395 is configured to predict a future battery value. For instance, as discussed throughout the application, the processor 395 may be configured to apply a battery value temporal convolutional neural network to one or more control profiles and/or sensor data received from one or more sensors at the battery pack 380 to predict one or more future values such as a future state of charge, temperature, voltage, current, or other such state. Battery value temporal convolutional neural networks are discussed in additional detail throughout the application, for instance with respect to FIG. 6.

The controller 394 also includes the communication interface 399. According to various embodiments, the communication interface 399 may communicate with one or more external devices, such as a remote computing system. The communication may take place via the internet or via another communication medium. The remote computing system may be configured to receiving battery measurement information, to process the battery measurement information in accordance with techniques and mechanisms described herein, and/or to transmit instructions to the battery pack 380 via the communication interface 399. For instance, the communication interface 399 may transmit to the remote computing system one or more measurements determined at the battery pack 380, and to receive an instruction determined based on a battery pack value predicted by the remote computing system.

### Examples of Control Systems and Devices

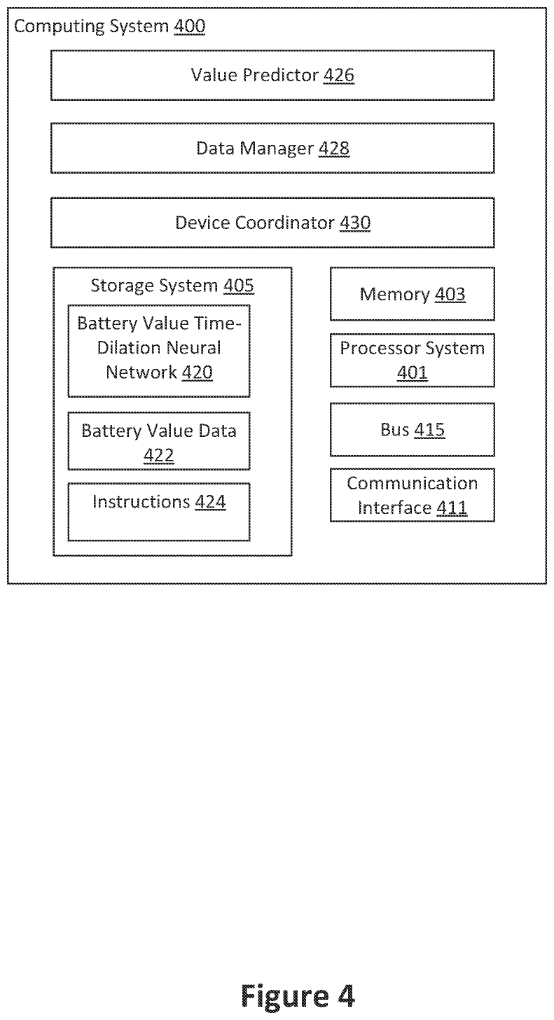

FIG. 4 illustrates one example of a computing system 400. According to various embodiments, a computing system 400 suitable for implementing embodiments described herein includes a processor system 401, a memory module 403, a storage system 405, a communication interface 411, and a bus 415 (e.g., a PCI bus or other interconnection fabric.) Computing system 400 may operate as variety of devices such as a battery management system, a fleet control system, a local device controller, a battery pack controller, a remote device controller, or any other device or service described herein. Although a particular configuration is described, a variety of alternative configurations are possible. The processor system 401 may include one or more physical processors and may perform operations such as those described herein. Instructions 424 for performing such operations may be embodied in the memory 403, on one or more non-transitory computer readable media, in the storage system 405, and/or on some other storage device. Various specially configured devices can also be used in place of or in addition to the processor system 401.

The storage system 405 includes a battery value temporal convolutional neural network 420, battery value data 422, and instructions 424. The computing system 400 includes a value predictor 426, a value data manager 428, and a device coordinator 430, one or more of which may operate on the basis of the instructions 424. According to various embodiments, the value predictor 426 may be configured to train the battery value temporal convolutional neural network 420 and/or to predict future battery values based on the battery value temporal convolutional neural network 420. Such predictions may be made based at least in part on the battery value data 422, which may store battery value data for one or more battery systems.

According to various embodiments, the battery data manager 428 may manage the battery value data 422. For example, the battery data manager 428 may receive sensor data, control data, or other battery value information and store battery value data 422 based on the received information. As another example, the battery value data manager 428 may determine actual and/or simulated training datasets based on physics model information. The training datasets may be stored as the storage system 405.

According to various embodiments, the device coordinator 420 may be responsible for coordinating communications with and instructions to and/or from one or more local and/or remote devices. For example, the device coordinator 420 may function as a battery management system. As another example, the device coordinator 420 may provide fleet control functionality for a fleet of devices. As another example, the device coordinator 420 may provide command and control functionality for any device that includes a battery system.

The communication interface 411 may be configured to send and receive data packets over a network, bus, or other communication link. For example, the communication interface 411 may be configured to communicate with a battery pack via the internet. As another example, the communication interface 411 may be configured to communicate with a battery cell via a bus. The communication interface 411 and associated components may include ports appropriate for communication with the appropriate media. They may also include an independent processor and/or volatile RAM. A computer system or computing device may include or communicate with a monitor, printer, or other suitable display for providing any of the results mentioned herein to a user.

### Examples of a Battery Value Temporal Convolutional Neural Network

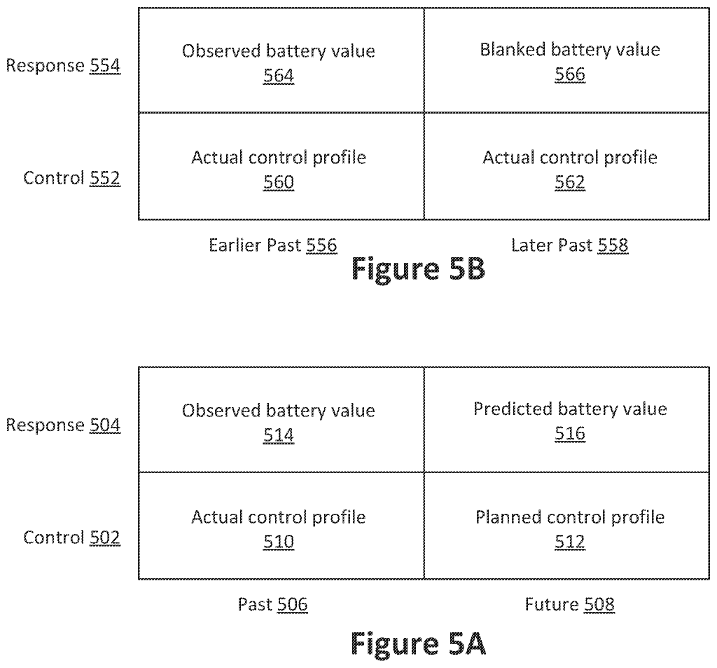

FIG. 5A illustrates a conceptual diagram of a prediction framework for a battery system in an inference phase. FIG. 5A shows battery information during the past time period 506 and future time period 508. The battery information is divided into the control data 502 and the response data 504.

According to various embodiments, the control data 502 includes information pertaining to a control profile provided to a battery system. For instance, the control profile may include data on current profile and/or power profile values measuring a charge/discharge rate of a battery system during one or more periods of time. Thus, the actual control profile information 510 corresponds to control profile data for actual control profiles applied to a battery system during one or more periods of time in the past. Similarly, the planned control profile information 512 corresponds to a control profile that is planned for the future and for which a prediction as to the resulting battery value is desired.

According to various embodiments, the response data 504 corresponds to an observed value of the battery system that occurs at least partially in response to the control profile at that point in time, and potentially also in response to historical data for the battery system as well. Thus, the observed battery value data 514 corresponds to battery value information that was observed in the past and that corresponds to the actual control profile information 510 in timing. The predicted battery value data 516 corresponds to desired information about the state of the battery system in the future in response to the planned control profile 512.

FIG. 5B illustrates a conceptual diagram of a prediction framework for a battery system in a training phase. Because FIG. 5B corresponds to a training phase in which outcome data is available, all of the information reflected in FIG. 5B is necessarily from the past. However, the training data may be observed or simulated, as discussed with respect to FIGS. 7-11. Thus, FIG. 5B shows battery information during an earlier past time period 556 and a later past time period 558. The battery information is again divided into the control data 552 and the response data 554.

According to various embodiments, the control data 552 includes information pertaining to a control profile provided to a battery system, as with the control data 552. Thus, the actual control profile data 560 and 562 correspond to control profiles applied in different periods in the past.

According to various embodiments, the response data 554 corresponds to an observed value of the battery system that occurs at least partially in response to the control profile at that point in time, and potentially also in response to historical data for the battery system as well. Thus, the observed battery value data 564 corresponds to battery value information that was observed in the past and that corresponds to the actual control profile information 560 in timing. The blanked battery value data 566 also corresponds to battery value information that was observed in the past but that instead corresponds to the actual control profile information 562 in timing.

In some embodiments, for the purpose of model training, the blanked battery value data 566 may be selectively blanked. Then, the model may be applied to try to predict the blanked battery value data 566. The actual values of the blanked battery value data 566 may then be used to update the weights of the model, for instance in a back propagation phase. This process may be repeated to train the model to predict the battery value.

FIG. 6 illustrates a diagram of a battery value temporal convolutional neural network 420, configured in accordance with one or more embodiments. The battery value temporal convolutional neural network 420 includes a number of neurons in communication with one another. According to various embodiments, the battery value temporal convolutional neural network 420 is configured to predict battery values at a future time t based on observed battery value information, past control profile information, and future control profile information.

In some embodiments, the battery value temporal convolutional neural network 420 may be implemented at a battery system. For instance, the battery value temporal convolutional neural network 420 may be implemented at a battery management system controller.

In some embodiments, the battery value temporal convolutional neural network 420 may be implemented at a remote computing system. For instance, the battery value temporal convolutional neural network 420 may be implemented in a cloud computing environment, a fleet management server, or any other suitable computing system in communication with a battery system via a network or communication bus.

The neurons in the battery value temporal convolutional neural network 420 are divided into layers, including a battery data input layer 602, a hidden layer 1 604, a hidden layer 2 606, and a battery value output layer 608. Although the diagram illustrated in FIG. 6 includes only two hidden layers for the purpose of illustration, in practice a battery value temporal convolutional neural network may include various numbers of hidden layers. For instance, a battery value temporal convolutional neural network may include one, two, ten, or any suitable number of layers.

In some embodiments, a neuron in the battery value output layer 608 corresponds to one or more predicted values associated with a battery state at a point in time. For instance, the neuron 630 corresponds to a battery state at time t+2, while the neuron 634 corresponds to a battery state at time t+1, where t is the current point in time.

According to various embodiments, the predicted battery values associated with a neuron in the battery value output layer 608 may include any of a variety of information about a battery system. Such information may include, but is not limited to: battery response values, battery parameter values, and/or battery state values.

According to various embodiments, the state information may be determined for any suitable level of analysis of a battery system. For instance, the value information may be determined at the level of the battery system, the battery pack, or the battery node, depending on the availability of data.

According to various embodiments, a neuron in the battery data input layer may correspond to input data during a period of time. For instance, the neurons 612, 614, 616, and 618 correspond to input data at time t−1, t, t+1, and t+2, respectively.

According to various embodiments, the input data may include any or all of past control profile information, future control profile information, observed battery value information, and/or predicted battery value information. For example, to predict the one or more battery values 630 at time t+2, the input layer neurons 612 and 614 may encode observed battery value information and actual control profile information at times t−1 and t, respectively. However, because the times t+1 and t+2 are in the future, the input layer neuron 616 may encode predicted battery value information and future (i.e., hypothetical) control profile information for times t+1 and t+2, as discussed conceptually with respect to FIG. 6.

According to various embodiments, a neuron in the battery value temporal convolutional neural network 420 may include an activation function. For instance, the activation function may be a rectified linear unit (ReLU) activation function. However, any suitable activation function may be employed. The activation function may activate to send an output signal based on inputs to the neuron and one or more weights learned in a training phase.

In the battery value temporal convolutional neural network 420 shown in FIG. 6, each neuron past the battery data input layer 602 receives as input signals from two different input neurons. For example, the neuron 626 receives input signals from the neurons 616 and 618, while the neuron 622 receives input signals from the neurons 612 and 614. In practice, neurons in different battery value temporal convolutional neural networks may receive various numbers of input signals, depending on the configuration.

The configuration of the battery value temporal convolutional neural network 420 is such that a neuron in a hidden layer effectively dilates time by receiving as input signals generated by neurons corresponding to two or more periods of time but producing only a single output. For instance, the neuron 626, although positioned in the period t+2, encompasses input signals from both the periods t+1 and t+2. Similarly, the neuron 628, although also positioned in the period t+2, encompasses input signals from the periods t−1, t, t+1 and t+2. In this way, information from a potentially lengthy period of time may be collapsed into a small number of neurons. For instance, the neuron 630 reflects information from the period of time ranging from t−6 to t+2, by virtue of its input signals received from both the neuron 632 and the neuron 628.

In some embodiments, some neurons may not contribute to an output signal at a particular period of time. For instance, the dotted arrows illustrate signals that are not employed when predicting the battery state at time t+2 but that may be employed when predicting the battery state at a different point in time. As one example, when predicting the battery state at time t+2, the neuron 624 is not employed due to the nature of the time dilation. For time t+2, the neurons 614 and 616 send their input signals to the neurons 622 and 626 instead. However, the neuron 624 would be employed when predicting the battery state output layer neuron 634 at time t+1.

According to various embodiments, battery value temporal convolutional neural networks may have various numbers of neurons and layers. For example, the diagram illustrated in FIG. 6 includes only 32 neurons for the purpose of illustration. However, in practice, different battery value temporal convolutional neural networks may include different numbers (e.g., hundreds, thousands, or millions) of neurons. As another example, the diagram illustrated in FIG. 6 includes only 2 hidden layers for the purpose of illustration. However, in practice, different battery value temporal convolutional neural networks may include different numbers (e.g., one, two, ten, hundreds, or thousands) of hidden layers. Increasing the number of hidden layers may result in a neural network capable of taking into account more input data, since a number of neurons in a hidden layer can dilate two or more times that number of neurons in an earlier layer. However, increasing the number of hidden layers may also result in a neural network that requires more space to store and/or more time to train.

In particular embodiments, one or more characteristics of the battery value temporal convolutional neural network may be determined by hyperparameter tuning. Examples of characteristics that may be tuned as hyperparameters include, but are not limited to: the number of neurons, the number of hidden layers, the degree of time dilation, the number of inputs to a given neuron, and the types of information included in the battery data input layer 602.

### Training a Battery Value Temporal Convolutional Neural Network

FIG. 7 illustrates an overview method 700 of training a battery value temporal convolutional neural network. According to various embodiments, the method 700 may be performed at any suitable computing device to train a battery value temporal convolutional neural network prior to deployment, when observed data is not yet available, and to update the battery value temporal convolutional neural network after deployment, after observed data is available. The method 700 may be triggered as discussed with respect to operation 102 shown in FIG. 1.

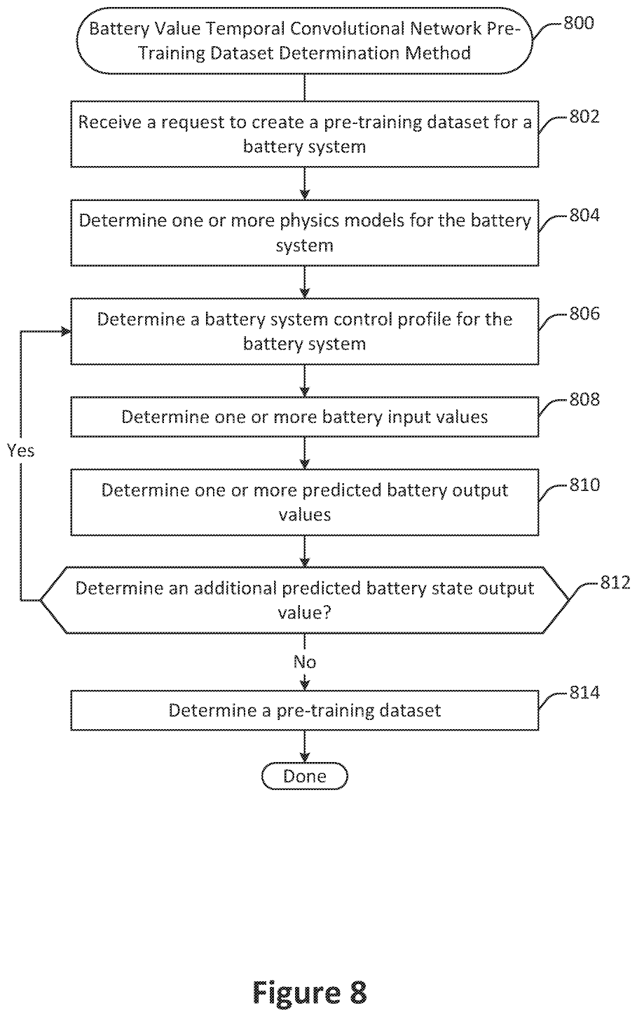

A pre-training dataset is determined at 702 based on one or more theoretical models. According to various embodiments, a theoretical model may define one or more theoretical interactions between control parameters and observed values associated with a battery system. For instance, a theoretical model may predict a temperature and a voltage for a battery system when a current profile and/or power profile is applied. Such models may be based on the characteristics of a given battery system. Additional details regarding the determination of a pre-training dataset are discussed with respect to the method 800 shown in FIG. 8.

According to various embodiments, some types of battery values may only be predicted by incorporating a pre-training phase into the training of a battery value temporal convolutional neural network. For example, one or more parameters and/or states may be hidden values that are employed in a physics model but never directly observed by sensors in a battery system. For example, resistance and/or capacitance values for an equivalent circuit model may be hidden. As another example, electrolyte connectivity values and/or cathode conductivity values for a pseudo-two-dimensional (P2D) model may be hidden.

For the purpose of exposition, this application is described as including a pre-training phase prior to training based on observed data. However, in some embodiments, this ordering may be reversed. For instance, observed data may be used to train a battery value temporal convolutional network before updating the neural network using data from one or more physics models.

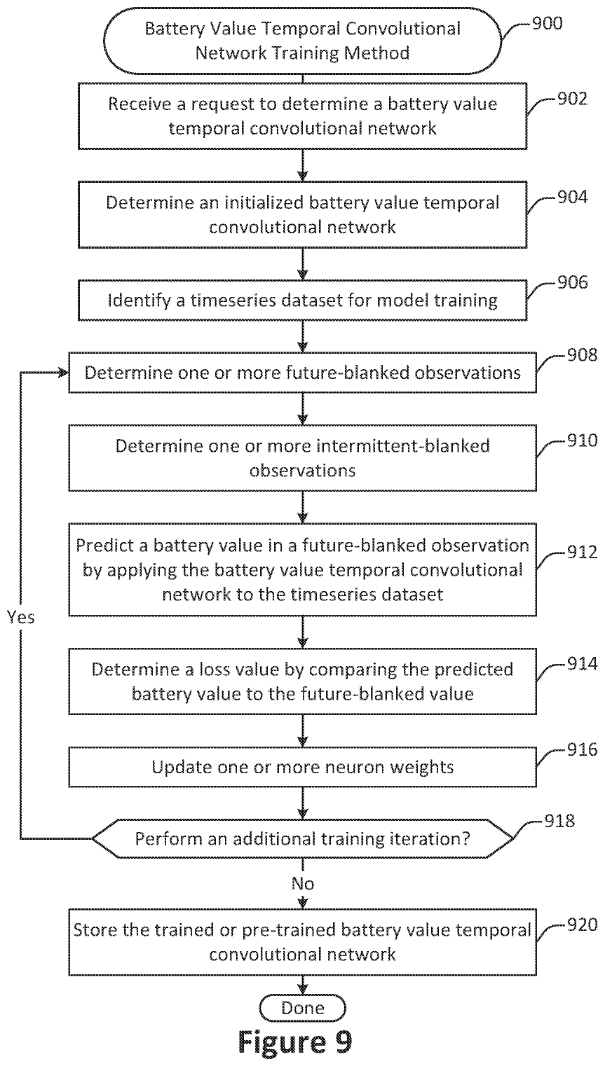

A pre-trained battery value temporal convolutional neural network is determined at 704 based on the pre-training dataset. According to various embodiments, determining the pre-trained battery value temporal convolutional neural network may involve predicting one or more values blanked in the pre-training dataset, and then updating one or more weights in the battery value temporal convolutional neural network (e.g., using back propagation) based on the known value. Additional details regarding the determination of a pre-trained battery value temporal convolutional neural network are discussed with respect to the method 900 shown in FIG. 9.

An observed data training dataset is determined at 706 based on observed data. In some embodiments, the observed data training dataset may be determined by first deploying the pre-trained battery value temporal convolutional neural network for use with one or more actual battery systems to predict battery values in a lab environment and/or a field environment. Then, control profile data and battery value data may be collected and used to determine the observed data training dataset, for instance as discussed with respect to FIG. 5B.

A trained battery value temporal convolutional neural network is determined at 708 based on the training dataset. In some implementations, the trained battery value temporal convolutional neural network may be determined in a manner similar to the way in which the pre-trained battery value temporal convolutional neural network is determined, with the exception of the use of different training data. Also, transfer learning may be used to initialize weights of the trained battery value temporal convolutional neural network with the model weights from the pre-trained battery value temporal convolutional neural network.

In particular embodiments, different battery value temporal convolutional neural networks may be trained at different time scales. For example, one battery value temporal convolutional neural network may be trained to determine a predicted value based on time dilation corresponding to a period on the order of 100 seconds, while another battery value temporal convolutional neural network may be trained to determine a predicted value based on a time dilation corresponding to a period on the order of 10,000 seconds.

In particular embodiments, a battery value temporal convolutional neural network may be trained in layers. For example, an initial battery value temporal convolutional neural network may be trained to determine a predicted value based on time dilation corresponding to a period on the order of 100 seconds. One or more additional hidden layers may then be added to the hidden layers in the initial battery value temporal convolutional neural network to determine a network capable of making a prediction corresponding to a longer period of time. In some configurations, the initial weights may be frozen, which may prioritize predictions on shorter periods of time. In other configurations, the initial weights may be treated as inputs for transfer learning purposes but updated based on later training, which may prioritize predictions on longer periods of time.

FIG. 8 illustrates a method 800 for determining a battery value temporal convolutional neural network pre-training dataset, performed in accordance with one or more embodiments. The method 800 may be performed at any suitable computing system, such as the computing system 400 shown in FIG. 4.

A request to create a pre-training dataset for a battery system is received at 802. In some embodiments, the request may be generated as discussed with respect to operation 702 shown in FIG. 7. The request may identify a particular type of battery system for which the pre-training dataset will be used.

One or more physics models for the battery system are determined at 804. According to various embodiments, any of various physics models may be employed. For example, an equivalent circuit model (ECM) uses a circuit component to form a specific circuit network to characterize the operational characteristics of a battery circuit. As another example, a pseudo two-dimensional model (P2D) may capture electrochemical processes within a battery.

A battery system control profile is determined for the battery system at 806. In some embodiments, a control profile may include values for a current profile and/or power profile applied to the battery system over a period of time. Alternatively, or additionally, a control profile may include other types of information such as the ambient operating temperature of the battery system.

According to various embodiments, different battery system control profiles may be employed so that the pre-trained battery value temporal convolutional neural network is suitable for determining predictions in various types of contexts. The particular control profiles employed may correspond to situations likely to be encountered in a field and/or lab environment. For example, control profiles may be determined using a sigmoid basis, a sinusoidal basis, or another such functional basis. As another example, control profiles may be determined based on actual data, for instance data collected from a laboratory environment and/or a field environment.

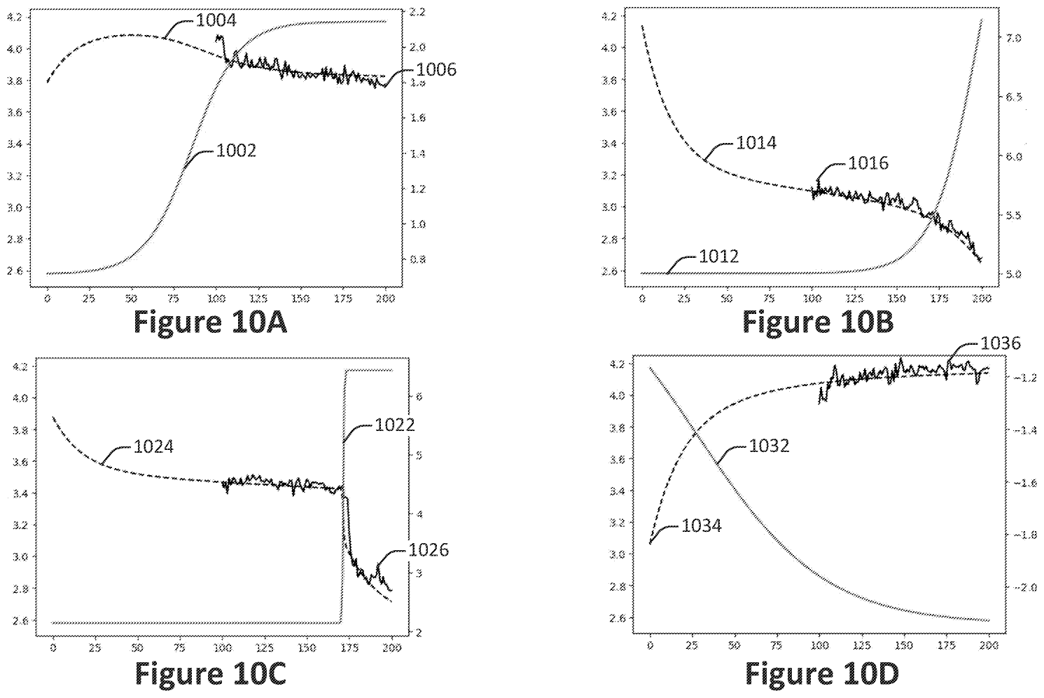

FIG. 10A, FIG. 10B, FIG. 10C, and FIG. 10D illustrate examples of plots generated in accordance with one or more embodiments. In FIG. 10A, FIG. 10B, FIG. 10C, and FIG. 10D, the lines 1002, 1012, 1022, and 1032 correspond to different control profiles that may be employed. Each control profile is specified as a current profile and/or power profile over time and is represented on the right-side y-axis. The control profiles 1002, 1012, 1022, and 1032 were generated using a sigmoid basis. However, as discussed herein, various approaches may be used to generate a control profile.

Returning to FIG. 8, one or more battery input values are determined at 808. According to various embodiments, a battery input variable may be a portion of a battery state that is assumed for the purpose of predicting another aspect of the battery state. For example, a battery state may include both temperature and voltage. However, to create a pre-training dataset, a temperature variable may be fixed and used to estimate a current variable under a particular set of conditions. As another example, a battery input value may include a battery value from a previous time period.

One or more predicted battery output values are determined at 810. In some embodiments, the one or more predicted battery output values may be determined by applying the one or more physics models to the battery system control profile and the one or more battery input values. In some configurations, a single physics model may be used to predict a battery output value. Alternatively, different physics models may be chained together to collectively predict a battery output value.

In FIG. 10A, FIG. 10B, FIG. 10C, and FIG. 10D, the lines 1004, 1014, 1024, and 1034 correspond to battery output values—in this case, voltage—predicted by one or more physics models. However, as discussed herein, various predicted battery outcome values may be determined, not only voltage values.

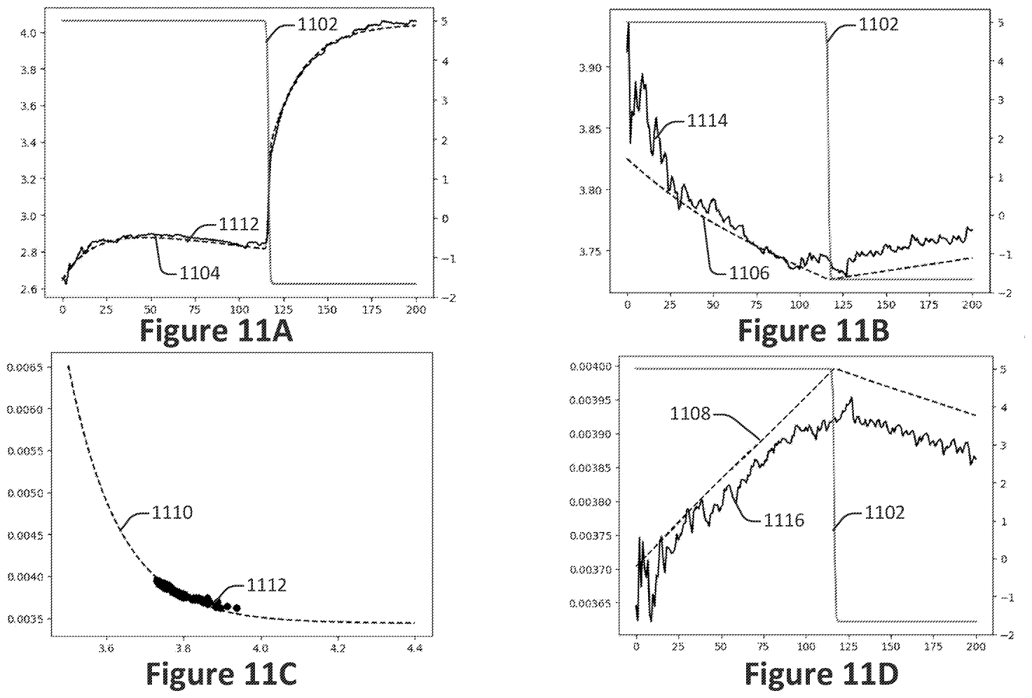

For example, FIG. 11A, FIG. 11B, FIG. 11C, and FIG. 11D illustrate examples of plots generated in accordance with one or more embodiments. In FIG. 11A, FIG. 11B, and FIG. 11C, the same control profile is shown at 1102, while different types of outcome values are predicted. For instance, the dotted line 1104 corresponds to voltage, the dotted line 1106 corresponds to open-circuit voltage, and the dotted line 1108 corresponds to internal resistance. In FIG. 10, the line 1110 shows internal resistance on the y-axis as predicted by the physics model as a function of predicted open-current voltage on the x-axis.

Returning to FIG. 8, a determination is made at 812 as to whether to determine an additional battery output value. In some embodiments, the determination may be made based at least in part on whether a sufficient amount of data has been generated. For instance, data may be generated for each of a set of physics models, a set of control profiles, and/or a set of battery input values.

A pre-training dataset is determined at 814. In some embodiments, the pre-training dataset may be determined by combining the control profile data, the battery input values, and the predicted battery output values to create a time-series dataset that includes battery values at various points in time.

According to various embodiments, pre-training datasets may be determined for different time scales. For instance, a period of time in a pre-training dataset may correspond to a second, a fraction of a second, or multiple seconds.

According to various embodiments, operations shown in FIG. 8 may be performed in an order different than that shown. Alternatively, or additionally, one or more operations may be omitted. For example, operations 806 through 812 may be performed in parallel. As another example, a battery input value need not be employed in the pre-training dataset determination process.

According to various embodiments, control profile values, battery input values, and/or battery output values may each include one or more of a variety of types of data. Examples of values that may be included in a pre-training dataset include, but are not limited to: time (e.g., measured in seconds), voltage (e.g., measured in volts), current (e.g., measured in amperes), power (e.g., measured in watts), open circuit voltage (e.g., measured in volts), differential voltage (i.e., dV/dQ), internal resistance (e.g., measured in ohms), external resistance (e.g., measured in ohms), current profile (charge or discharge current/capacity) and/or power profile.

FIG. 9 illustrates a method 900 for training a battery value temporal convolutional neural network, performed in accordance with one or more embodiments. According to various embodiments, the method 900 may be performed at any suitable computing device.

A request to determine a battery value temporal convolutional neural network is received at 902. The request may be generated based on an automated process or may be generated based on user input. The request may identify one or more characteristics of a battery system for training the network, characteristics which may be used to determine one or more configuration parameters and/or training datasets.

An initialized battery value temporal convolutional neural network is determined at 904. In some embodiments, the initialized battery value temporal convolutional neural network may be a neural network that has not yet been trained but that has been configured based on one or more configuration parameters. Examples of such configuration parameters may include, but are not limited to: a number of neurons, a number of hidden layers, a degree of time dilation, initial weights, neuron activation functions, types of input data, types of values predicted by the network, and/or any other parameters.

In some embodiments, the initialized battery value temporal convolutional neural network may be a trained battery value temporal convolutional neural network that was previously trained and is being updated in the method 900 shown in FIG. 9. For instance, a battery value temporal convolutional neural network may be initially trained using a pre-training dataset and then be updated with application data as such data becomes available.

According to various embodiments, one or more configuration parameters may be determined based on user input. Alternatively, or additionally, one or more configuration parameters may be selected based on characteristics of the battery system.

In particular embodiments, one or more configuration parameters may be determined based on hyperparameter tuning. For instance, different battery value temporal convolutional neural networks may be trained using different combinations of hyperparameters, with the trained battery value temporal convolutional neural network selected that performs best according to one or more performance metrics.

A timeseries dataset for model training is identified at 906. In some embodiments, the timeseries dataset may be determined as discussed with respect to the method 800 shown in FIG. 8. Alternatively, or additionally, a timeseries dataset may include application data determined based on operations in a field and/or laboratory setting, as discussed with respect to FIG. 2.

One or more future-blanked observations are determined at 908. According to various embodiments, a future-blanked observation may be any observation in the timeseries dataset where a value capable of being predicted by the model is masked or blanked. The masked or blanked value may be reserved so that when it is predicted by the model, the predicted value may be compared with the actual value for the purpose of training.

According to various embodiments, an observation to future-blank may be selected in any suitable order, in sequence or in parallel. For example, a set of observations may be future-blanked and used to train the model in temporal sequence. As another example, observations may be selected at random for future-blanking and training from a time-series dataset. As discussed in more detail below, observations may also be selected for past-blanking.

At 910, one or more intermittent-blanked observations are optionally determined. In many real world applications, the data available for predicting a value of a battery system includes one or more missing values due to factors such as sensor faults and the like. Accordingly, in some embodiments, one or more values normally used by the battery value temporal convolutional neural network to predict a battery value may be artificially blanked to simulate such a situation. Intermittently blanking one or more data values in such a way may lead to the construction of a battery value temporal convolutional neural network that is more robust to missing data than would otherwise be the case. Observations may be selected for intermittent-blanking at random or according to any suitable selection criteria.

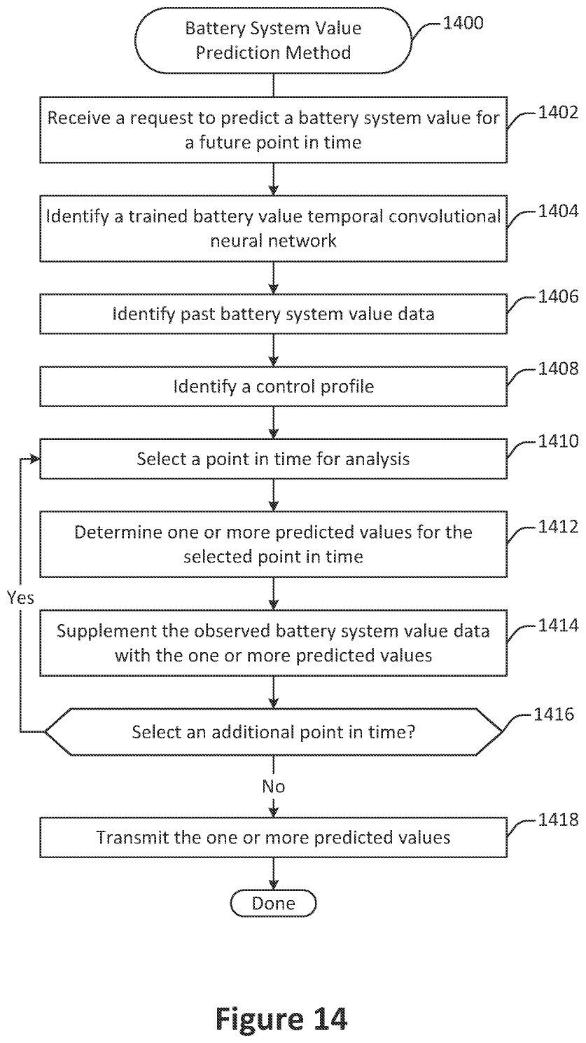

A battery value in a future-blanked observation is selected by applying the battery value temporal convolutional neural network to the timeseries dataset after future-blanking and optional intermittent-blanking. Additional details regarding the application of the battery value temporal convolutional neural network to timeseries data to produce a prediction are discussed throughout the application as filed, for instance with respect to the method 1400 shown in FIG. 14.

A loss value is determined at 914 by comparing the predicted battery value to the future-blanked value. According to various embodiments, any of a variety of loss functions may be used. For instance, the loss function may impose a loss value penalizing the square of the loss.

One or more neuron weights are updated at 916. In some embodiments, neuron weights may be updated using a backpropagation and gradient descent.

A determination is made at 918 as to whether to perform an additional training iteration. According to various embodiments, training may continue until one or more criteria are satisfied. For example, training may continue until successive training iterations yield a limited improvement in model performance. As another example, training may continue until all or a designation proportion of the available training data has been analyzed. As yet another example, training may continue until a designated number of training iterations have been performed.

The trained or pre-trained battery value temporal convolutional neural network is stored at 920. The trained or pre-trained model may then be used for predicting battery values, as discussed throughout the application.

According to various embodiments, a training process for training a battery value temporal convolutional neural network may include one or more operations not shown in FIG. 9. For example, k-fold validation may be used to avoid overfitting the model. As another example, training may be divided into epochs, as discussed with respect to the method 700, for instance to train the model using data having different time scales.

### Applying a Battery Value Temporal Convolutional Neural Network

FIG. 12 illustrates a method 1200 of controlling a device, performed in accordance with one or more embodiments. The device may include a battery system and may be controlled by selecting a control profile for the battery system and then identifying a course of action corresponding to the selected control profile. The control profile may be selected based at least in part on a battery value predicted by a battery value temporal convolutional neural network.

According to various embodiments, the method 1200 may be employed for various types of devices. Examples of such devices may include, but are not limited to: autonomous robots, user-controlled robots, autonomous vehicles, user-controlled vehicles, or any other type of device having a battery system.

In some embodiments, the method 1200 may be performed at least in part at the device itself. For instance, the method 1200 may be performed in a device controller and/or in a battery management system within the device.

In some embodiments, the method 1200 may be performed at least in part at a remote computing system. For instance, a remote computing system may communicate with the device via a network. The remote computing system may then select a control profile based on information associated with the device and then transmit to the device an indication of the control profile and/or a course of action corresponding with the selected control profile.

A request to perform an action is received at 1202. In some embodiments, the request may include information capable of being used to identify a battery load needed to perform the requested action. For example, the request may identify one or more vehicle or robot destinations, operations, loads, or other such information.

One or more candidate control profiles for performing the action are determined at 1204. According to various embodiments, techniques for determining the candidate control profiles may depend in significant part on the particular application in which the predicted battery system value data is determined. For example, in the robotics context, different candidate control profiles may correspond to different candidate sequences of actions to be performed by a robot to accomplish a goal. As another example, in the vehicle context, different candidate control profiles may correspond to different routes that may be traveled to reach one or more destinations.

A trained battery value temporal convolutional neural network is identified at 1206. According to various embodiments, trained battery value temporal convolutional neural network may have been trained as discussed with respect to FIG. 7, FIG. 8, FIG. 9, FIG. 10, and FIG. 11. The temporal convolutional network need not have been trained using the specific battery system included in the device, but rather need only have been trained to predict battery values for battery systems of the type included in the device.

A candidate control profile is selected at 1208. According to various embodiments, candidate control profiles may be analyzed in any suitable order, in sequence or in parallel.

Input battery system value data for the device is determined at 1210. According to various embodiments, the input battery system value data may include various types of information. For example, the input battery system value data may include information collected from one or more sensors at the device. Such information may include characteristics such as temperature and current associated with a battery system. As another example, the input battery system value data may include historical information associated with the battery system and determined during previous time intervals. Such information may be retrieved from a storage device or a memory module where it was stored for later use. As yet another example, the input battery system value data may include any information regarding the present or past performance, control, and/or characteristics of the battery system or device.

Predicted battery system value data for the device is determined at 1212. In some embodiments, the predicted battery system value data may be determined by applying the trained battery value temporal convolutional neural network to the input battery system value data determined at 1210. As discussed throughout the application, for instance with respect to FIG. 6, the input battery system value data may be arranged as a timeseries dataset that includes multiple observations for one or more battery system values over a period of time. The trained battery value temporal convolutional neural network may be applied to this timeseries dataset to determine one or more predicted battery system values. Additional details regarding such as process are discussed with respect to the method 1400 shown in FIG. 14.

At 1214, a determination is made as to whether to select an additional control profile for analysis. In some embodiments, additional control profiles may continue to be selected until all identified control profiles have been analyzed. Alternatively, or additionally, another type of terminating condition may be employed. For instance, additional control profiles may continue to be selected until a control profile is identified that meets one or more selection criteria.

A control profile for performing the action is selected at 1216 based at least in part on the predicted battery system value data. According to various embodiments, the criteria employed for selecting the control profile may depend in significant part on the particular application, and thus may be strategically determined based on any of a variety of considerations.

In some embodiments, selecting the control profile may involve determining which control profile analyzed as discussed with respect to operations 1208 through 1212 is associated with the best predicted battery system state. For instance, the control profile that leaves the battery system with the maximum amount of remaining charge may be selected.

In some embodiments, the control profile may be selected to ensure that the device does not drop below a minimum state of charge at any time during the execution of the control profile.

In some embodiments, the control profile may be selected based on more than one criteria. For instance, the control profile may be selected that is associated with the course of action having the shortest path, subject to a constraint such that the battery system need be left with at least a designated amount of charge remaining after executing the selected control profile.

An instruction is transmitted to the device at 1218. In some embodiments, the instruction may identify the control profile. Alternatively, or additionally, the instruction may identify a course of action corresponding with the selected control profile.

According to various embodiments, as discussed herein, the instruction may be sent to the device from a remote computing system. Alternatively, the instruction may be sent from a controller operating at the device itself, either inside or outside the battery system.

According to various embodiments, the method 1200 shown in FIG. 12 may be employed in any of a variety of circumstances. For instance, the method 1200 may be used to diagnose excessive battery usage by determining a alternative control profile for a device different than what was actually used, which may help to provide guidance as to better battery usage. As another example, the method 1200 may be used in a research and development setting to develop instructions for devices to improve their battery usage and hence their performance.

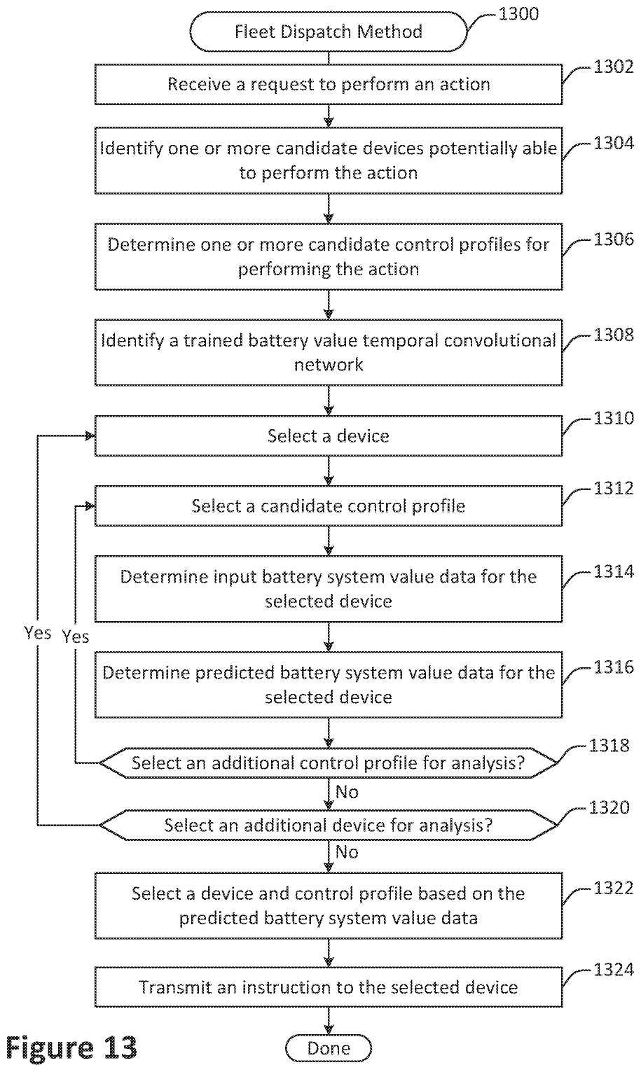

FIG. 13 illustrates a method 1300 of controlling a fleet of devices, performed in accordance with one or more embodiments. One or more of the devices may include a battery system. The fleet of devices may be controlled by selecting a device and a control profile for the battery system and then identifying a course of action corresponding to the selected control profile. The control profile and the device may be selected based at least in part on a battery value predicted by a battery value temporal convolutional neural network.

According to various embodiments, the method 1300 may be employed for various types of devices. Examples of such devices may include, but are not limited to: autonomous robots, user-controlled robots, autonomous vehicles, user-controlled vehicles, or any other type of device having a battery system.

In some embodiments, the method 1300 may be performed at least in part at a remote computing system. For instance, a remote computing system may communicate with the fleet of devices via a network. The remote computing system may then select a device and a control profile for the device based on information associated with the device and then transmit an indication of the control profile and/or course of action corresponding to the control profile to the selected device.

A request to perform an action is received at 1302. In some embodiments, the request may include information capable of being used to identify a battery load needed to perform the requested action. For example, the request may identify one or more vehicle or robot destinations, operations, loads, or other such information.

One or more candidate devices potentially able to perform the action are identified at 1304. The devices may be identified by a fleet management system tasked with managing the devices. In some embodiments, all available devices may be identified. Alternatively, a subset of the devices meeting one or more criteria may be identified. For example, the identified devices may include those in the vicinity of an area in which the requested action is to be performed. As another example, the identified devices may include those having a designated amount of charge remaining in a battery system. Various criteria are possible, and may be strategically determined based on the characteristics of the devices and the requested action.

One or more candidate control profiles for performing the action are determined at 1304. According to various embodiments, techniques for determining the candidate control profiles may depend in significant part on the particular application in which the predicted battery system value data is determined. For example, in the robotics context, different candidate control profiles may correspond to different candidate sequences of actions to be performed by a robot to accomplish a goal. As another example, in the vehicle context, different candidate control profiles may correspond to different routes that may be traveled to reach one or more destinations.

In some embodiments, multiple devices may have the same candidate control profiles. For instance, a fleet of devices may include two or more similar devices located in approximately the same place. Alternatively, or additionally, different devices may have different control profiles. For instance, a fleet may include devices that differ in characteristics such as location, condition, battery systems, capabilities, and/or other such attributes. In such a situation, different devices may need different sequences of operations to perform a requested action and hence be associated with different control profiles.

A trained battery value temporal convolutional neural network is identified at 1308. According to various embodiments, trained battery value temporal convolutional neural network may have been trained as discussed with respect to FIG. 7, FIG. 8, FIG. 9, FIG. 10, and FIG. 11. The temporal convolutional network need not have been trained using the specific battery system included in the device, but rather need only have been trained to predict battery values for battery systems of the type included in the device.

In some embodiments, multiple trained battery value temporal convolutional neural networks may be identified. For instance, different devices in the fleet may be equipped with different battery systems corresponding with different battery value temporal convolutional neural networks.

A device is selected at 1310. A candidate control profile is selected at 1312. According to various embodiments, devices and candidate control profiles may be analyzed in any suitable order, in sequence or in parallel.

Input battery system value data for the selected device is determined at 1314. According to various embodiments, the input battery system value data may include various types of information. For example, the input battery system value data may include information collected from one or more sensors at the device. Such information may include characteristics such as temperature and current associated with a battery system. As another example, the input battery system value data may include historical information associated with the battery system and determined during previous time intervals. Such information may be retrieved from a storage device or a memory module where it was stored for later use. As yet another example, the input battery system value data may include any information regarding the present or past performance, control, and/or characteristics of the battery system or device.

Predicted battery system value data for the selected device is determined at 1316. In some embodiments, the predicted battery system value data may be determined by applying the trained battery value temporal convolutional neural network to the input battery system value data determined at 1314. As discussed throughout the application, for instance with respect to FIG. 6, the input battery system value data may be arranged as a timeseries dataset that includes multiple observations for one or more battery system values over a period of time. The trained battery value temporal convolutional neural network may be applied to this timeseries dataset to determine one or more predicted battery system values. Additional details regarding such a process are discussed with respect to the method 1400 shown in FIG. 14.

At 1318, a determination is made as to whether to select an additional control profile for analysis. At 1320, a determination is made as to whether to select an additional device for analysis. In some embodiments, additional control profiles and devices may continue to be selected until all identified control profiles have been analyzed. Alternatively, or additionally, another type of terminating condition may be employed. For instance, additional control profiles and devices may continue to be selected until a device and associated control profile meeting one or more selection criteria are identified.

A device and control profile for performing the action is selected at 1322 based at least in part on the predicted battery system value data. According to various embodiments, the criteria employed for selecting the device and control profile may depend in significant part on the particular application, and thus may be strategically determined based on any of a variety of considerations.

In some embodiments, selecting the device and control profile may involve determining which device and control profile analyzed as discussed with respect to operations 1310 through 1320 are associated with the best predicted battery system state. For instance, the control profile that leaves the battery system with the maximum amount of remaining charge may be selected.

In some embodiments, the device and control profile may be selected based on more than one criteria. For instance, the device and control profile may be selected that is associated with the course of action having the shortest path, subject to a constraint such that the battery system at the device need be left with at least a designated amount of charge remaining after executing the selected control profile.

In some embodiments, the device and control profile may be selected to ensure that the selected device does not drop below a minimum state of charge at any time during the execution of the control profile.

An instruction is transmitted to the selected device at 1324. In some embodiments, the instruction may identify the control profile. Alternatively, or additionally, the instruction may identify a course of action corresponding with the selected control profile.

According to various embodiments, the method 1300 may be employed in a matching context, to determine a set of devices and control profiles predicted to be able to collectively perform a requested set of tasks.

FIG. 14 illustrates a method 1400 of predicting a value associated with a battery system, performed in accordance with one or more embodiments. The method 1400 may be performed at any suitable computing device. For instance, the method 1400 may be performed at a battery management system or at a remote computing system in communication with a battery management system on a device.

In some embodiments, the method 1400 may be performed at more device. For instance, an initial prediction may be made on an embedded device. Then, a more accurate prediction may be made at a remote system in communication with a battery management system on a device.

A request to predict a battery system value for a future point in time is received at 1402. According to various embodiments, the request may be generated as discussed with respect to operation 912 in FIG. 9, operation 1212 in FIG. 12, operation 1316 in FIG. 13, or in any other suitable application.

A trained battery value temporal convolutional neural network is identified at 1404. In some embodiments, the trained battery value temporal convolutional neural network may be determined as discussed with respect to the method 900 shown in FIG. 9.

Past battery system value data is identified at 1406. In some embodiments, the past battery system value data may correspond to an interval of time extending backward in time for a designated length, such as the last 60 seconds, 5 hours, or other length of time. The past battery system value data may include any input data used as input in the trained battery value temporal convolutional neural network. For instance, the past battery system value data may include values for parameters such as current profile and/or power profile, current, voltage, resistance, temperature, and/or any other values. According to various embodiments, the past battery system value data may be identified as discussed with respect to operations 906-910 in FIG. 9, operation 1210 in FIG. 12, operation 1314 in FIG. 13, or in any other suitable way.

A future control profile is identified at 1408. In some implementations, the future control profile may specify a current profile and/or power profile for the battery system at a time for which a battery value prediction is desired. For example, in FIG. 9, the future control profile may correspond to a future-blanked observation. As another example, in FIG. 12 and FIG. 13, the future control profile may correspond to a period of time in the future.

A point in time is selected for analysis at 1410. In some embodiments, points in time may be selected sequentially, at a timescale that reflects the timescale of the trained battery value temporal convolutional neural network. For instance, if a prediction is desired for a time period 20 seconds in the future and the model is trained using data at 1-second increments, the first of 20 periods of 1-second increments may initially be selected at 1410.

One or more predicted values are determined for the selected point in time at 1412. In some embodiments, the one or more predicted values may be determined as discussed with respect to the battery value temporal convolutional neural network 420 shown in FIG. 4.

In some embodiments, a predicted value corresponding to a state of the battery system may be a response value, such as a voltage that obtains when the control profile is applied. Examples of predicted values representing a response are shown at 1006 in FIG. 10A, 1016 in FIG. 10B, 1026 in FIG. 10C, and 1036 in FIG. 10D.

In some embodiments, a predicted value corresponding to a state of the battery system may be associated with a parameter other than a response value. For instance, in FIG. 11A, the jagged line 1112 corresponds to predicted voltage values, the jagged line 1114 corresponds to open-circuit voltage values, and the jagged line 1116 corresponds to internal resistance. In FIG. 10, the dots 1112 shows internal resistance on the y-axis as a function of predicted open-current voltage on the x-axis.

Returning to FIG. 14, the past battery system value data is supplemented with the one or more predicted values at 1414. In some embodiments, the predicted value data from one period used to predict the value data for the succeeding periods. In this way, value data may be made available for periods of time in between the present period of time and a future period of time for which a predicted value is desired.

A determination is made at 1416 as to whether to select an additional point in time for analysis. In some embodiments, additional points in time may continue to be selected until the future point in time identified at 1402 is reached. For instance, additional points in time may continue to be selected until the end of the control profile identified at 1410 is reached.

When it is determined not to select an additional point in time, the one or more predicted values are transmitted at 1418. According to various embodiments, depending on the application, the one or more predicted values may be transmitted to a storage system, a fleet management system, an embedded device, a device controller, or any other suitable destination.

### Control Profile Perturbation

FIG. 15 illustrates a method 1500 of determining a perturbed control profile, performed in accordance with one or more embodiments. The method 1500 may be performed at any suitable computing device.

According to various embodiments, the term “perturbed control profile” returns to a control profile having a current profile and/or power profile that has been altered so as to achieve a designated goal. For instance, a source control profile may be selected to achieve a particular objective, such as maximizing an amount of charge remaining in a battery system after performing a particular task. The source control profile may then be perturbed in some way to achieve a secondary objective.

In some implementations, a perturbed control profile may be determined for any of a variety of secondary objectives. For example, the source control profile may be perturbed in order to reduce uncertainty regarding a prediction as to a future battery value. As another example, the source control profile may be perturbed in order to generate additional training data exploring a state space. The resulting training data may then be used to update the battery value temporal convolutional neural network to improve its accuracy. As yet another example, the source control profile may be perturbed to ascertain additional information about battery health, for instance during a charging period.

A request to determine one or more perturbed control profiles based on a source control profile is received at 1502. According to various embodiments, the request may be optionally received whenever a control profile is determined. For instance, the request may be generated at operation 806 in FIG. 8, operation 1208 in FIG. 12, operation 1216 in FIG. 12, operation 1322 in FIG. 13, operation 1408 in FIG. 14, and/or at any other suitable point in time.

A set of candidate perturbed control profiles are identified at 1504. In some embodiments, a candidate perturbed control profile may be determined by altering the source profile. For example, a sinusoidal or sigmoid functional form may be applied to the current profile and/or power profile in the source control profile. As another example, randomly generated noise may be applied to the current profile and/or power profile in the source control profile. Such noise may be determined based on output generated by a random number generator. As yet another example, the current profile and/or power profile may be altered so that the total charge or discharge remains the same or similar but the shape of the current profile and/or power profile curve is varied.

At 1508, one or more predicted battery system values are determined based on the candidate perturbed control profile. According to various embodiments, values may be determined at one or more points in time in the future for any of a variety of possible parameters. Examples of such parameters may include, but are not limited to: voltage, current, resistance, temperature, and state of charge. The one or more predicted battery system values may be determined as discussed with respect to the method 1400 shown in FIG. 14.

One or more distribution parameter values corresponding with the one or more predicted battery system values are determined at 1510. In some embodiments, a distributional form may be assumed about a parameter associated with a predicted battery system value. For instance, an assumption may be made that the estimates follow a Gaussian distribution. Based on such an assumption, the comparison of predicted and actual parameter values during training may yield an estimate of a distributional parameter value such as variance. Such a distributional parameter may be predicted by the battery value temporal convolutional neural network in a manner similar to the prediction of any other value associated with the battery system.

In particular embodiments, a control profile variance value may be determined for a control profile based on one or more of the distribution parameter values corresponding with the one or more predicted battery values. The control profile variance value may correspond to an overall level of variance for the candidate perturbed control profile. The control profile variance value may be determined by averaging or otherwise combining one or more distribution parameter values for the candidate control profile.

At 1512, a determination is made as to whether to select an additional candidate perturbed control profile. According to various embodiments, additional candidate perturbed control profiles may continue to be selected until all identified candidate perturbed control profiles have been analyzed. Alternatively, or additionally, one or more other terminating conditions may be employed, such as the identification of a candidate perturbed control profile that meets one or more selection criteria.

A perturbed control profile is selected at 1514 based at least in part on the one or more distribution parameters. According to various embodiments, different types of selection criteria may be employed in different applications. For example, a control profile associated with the lowest (or relatively low) variance may be selected to improve the accuracy of the model's prediction. As another example, a control profile associated with the highest (or relatively high) variance may be selected to generate additional training data for retraining the model.

### CONCLUSION

In the foregoing specification, various techniques and mechanisms may have been described in singular form for clarity. However, it should be noted that some embodiments include multiple iterations of a technique or multiple instantiations of a mechanism unless otherwise noted. For example, a system uses a processor in a variety of contexts but can use multiple processors while remaining within the scope of the present disclosure unless otherwise noted. Similarly, various techniques and mechanisms may have been described as including a connection between two entities. However, a connection does not necessarily mean a direct, unimpeded connection, as a variety of other entities (e.g., bridges, controllers, gateways, etc.) may reside between the two entities.

In the foregoing specification, reference was made in detail to specific embodiments including one or more of the best modes contemplated by the inventors. While various implementations have been described herein, it should be understood that they have been presented by way of example only, and not limitation. For example, some techniques and mechanisms are described herein in the context of particular configurations of battery packs. However, the techniques of the present invention apply to a wide variety of battery systems. Particular embodiments may be implemented without some or all of the specific details described herein. In other instances, well known process operations have not been described in detail in order not to unnecessarily obscure the present invention. Accordingly, the breadth and scope of the present application should not be limited by any of the implementations described herein, but should be defined only in accordance with the claims and their equivalents.

1. A method comprising:
determining via a processor a plurality of control profiles for a designated type of battery system, each control profile defining a respective pattern of charging and/or discharging the designated type of battery system over a period of time;
determining a plurality of simulated battery values by applying one or more physics models to the plurality of control profiles via a processor, the one or more physics models modeling interactions between a plurality of states associated with the designated type of battery system;
determining via a processor a pre-trained battery value temporal convolutional neural network based on a timeseries pre-training dataset that includes the plurality of control profiles and the plurality of simulated battery values;
receiving as input a prospective control profile and observed battery system input values for a designated battery system of the designated type of battery system;
determining a predicted one or more battery values for the designated battery system based on application of the temporal convolutional neural network to the prospective control profile and the observed battery system input values; and
transmitting an operational instruction to the designated battery system based on the predicted one or more battery values.

2. The method recited in claim 1, wherein determining the pre-trained battery state for the designated battery system comprises introducing a plurality of blanked outcome values into the timeseries pre-training dataset, and wherein the pre-trained battery value temporal convolutional neural network is trained based on gradient descent via loss function reflecting a difference between predicted outcome values and blanked outcome values.

3. The method recited in claim 1, wherein determining the pre-trained battery state for the designated battery system comprises introducing a plurality of intermittent blanked values simulating missing data in the timeseries pre-training dataset.

4. The method recited in claim 1, wherein determining the plurality of control profiles comprises accessing a database storing field data characterizing operation of one or more physical battery systems over time.

5. The method recited in claim 1, wherein determining the plurality of control profiles comprises generating a function over time, the function being of a sinusoidal or sigmoid form.

6. The method recited in claim 1, wherein the one or more physics models includes a pseudo two-dimensional model characterizing one or more electrochemical processes with the designated type of battery system.

7. The method recited in claim 6, wherein the predicted one or more battery values include an electrolyte connectivity value or a cathode conductivity value.

8. The method recited in claim 1, wherein the one or more physics models includes an equivalent circuit model characterizing one or more operational characteristics of the designated type of battery system.

9. The method recited in claim 8, wherein the predicted one or more battery values include a resistance value or a capacitance value.

10. The method recited in claim 1, wherein a designated control profile of the plurality of control profiles includes a designated current profile defining an amount of current over a designated period of time.

11. The method recited in claim 1, wherein a designated control profile of the plurality of control profiles includes a designated power profile defining an amount of power over a designated period of time.

12. The method recited in claim 1, wherein the predicted one or more battery values includes a voltage value.

13. The method recited in claim 1, wherein the predicted one or more battery values includes a value selected from the group consisting of: an open-circuit voltage value, an internal resistance value, an external resistance value, a battery system temperature value, a state-of-charge value, and a state of health value.

14. The method recited in claim 1, wherein the temporal convolutional neural network includes an input layer comprising a plurality of input neurons, a subset of the input neurons corresponding to input battery data values observed of a plurality of time intervals.

15. The method recited in claim 12, wherein the input battery data values include control profile values encoding information corresponding with the plurality of control profiles.

16. The method recited in claim 1, wherein the temporal convolutional neural network includes one or more hidden layers each comprising a respective plurality of hidden layer neurons, a designated hidden layer neuron receiving as input data values corresponding to a respective two or more different time periods, the designated hidden layer neuron including an activation function configured to transmit an output signal to a recipient neuron based on the input data values.

17. The method recited in claim 14, wherein the hidden layers collectively perform time-dilation on a plurality of input values spread over a period of time to predict an output value corresponding to a single period of time.

18. One or more non-transitory computer readable media having instructions stored thereon for performing a method, the method comprising:
determining via a processor a plurality of control profiles for a designated type of battery system, each control profile defining a respective pattern of charging and/or discharging the designated type of battery system over a period of time;
determining a plurality of simulated battery values by applying one or more physics models to the plurality of control profiles via a processor, the one or more physics models modeling interactions between a plurality of states associated with the designated type of battery system;
determining via a processor a pre-trained battery value temporal convolutional neural network based on a timeseries pre-training dataset that includes the plurality of control profiles and the plurality of simulated battery values;
receiving as input a prospective control profile and observed battery system input values for a designated battery system of the designated type of battery system;
determining a predicted one or more battery values for the designated battery system based on application of the temporal convolutional neural network to the prospective control profile and the observed battery system input values; and
transmitting an operational instruction to the designated battery system based on the predicted one or more battery values.

19. A computing system including one or more processors, a communication interface, and a memory module, the computing system configured to perform a method comprising:
determining via a processor a plurality of control profiles for a designated type of battery system, each control profile defining a respective pattern of charging and/or discharging the designated type of battery system over a period of time;
determining a plurality of simulated battery values by applying one or more physics models to the plurality of control profiles via a processor, the one or more physics models modeling interactions between a plurality of states associated with the designated type of battery system;
determining via a processor a pre-trained battery value temporal convolutional neural network based on a timeseries pre-training dataset that includes the plurality of control profiles and the plurality of simulated battery values;
receiving as input a prospective control profile and observed battery system input values for a designated battery system of the designated type of battery system;
determining a predicted one or more battery values for the designated battery system based on application of the temporal convolutional neural network to the prospective control profile and the observed battery system input values; and
transmitting an operational instruction to the designated battery system via the communication interface based on the predicted one or more battery values.

20. The computing system recited in claim 19, wherein the temporal convolutional neural network includes one or more hidden layers each comprising a respective plurality of hidden layer neurons, a designated hidden layer neuron receiving as input data values corresponding to a respective two or more different time periods, the designated hidden layer neuron including an activation function configured to transmit an output signal to a recipient neuron based on the input data values, wherein the hidden layers collectively perform time-dilation on a plurality of input values spread over a period of time to predict an output value corresponding to a single period of time, wherein determining the pre-trained battery state for the designated battery system comprises introducing a plurality of blanked outcome values into the timeseries pre-training dataset, and wherein the pre-trained battery value temporal convolutional neural network is trained based on gradient descent via loss function reflecting a difference between predicted outcome values and blanked outcome values.
